(19) United States
(12) Patent Application Publication
(10) Pub. No.: US 2013/0000285 A1
(43) Pub. Date: Jan. 3, 2013

(54) INTERNAL COMBUSTION ENGINE EXHAUST THERMOELECTRIC GENERATOR AND METHODS OF MAKING AND USING THE SAME

(75) Inventor: Gregory P. Prior, Birmingham, MI (US)

(73) Assignee: GM GLOBAL TECHNOLOGY OPERATIONS LLC, Detroit, MI (US)

(21) Appl. No.: 13/170,996

(22) Filed: Jun. 28, 2011

(51) Int. Cl. F01N 5/02; B23K 1/00; H01L 35/32

(52) U.S. Cl. 60/320; 136/224; 228/101

(57) ABSTRACT

An internal combustion engine exhaust thermoelectric generator includes a stainless steel exhaust gas heat exchanger having an interior portion defined by a stainless steel wall and an exterior surface of the stainless steel wall distal to the interior portion. The exhaust gas heat exchanger receives a pressurized exhaust gas stream from the internal combustion engine and extracts thermal energy from the exhaust gas stream. At least one copper heat sink is in thermal contact with the exhaust gas heat exchanger to conduct thermal energy from the exhaust gas heat exchanger. A thermoelectric module has a hot side disposed on a surface of the at least one copper heat sink, and a cold side distal to the hot side. The thermoelectric module converts thermal energy to electrical energy for consumption or storage by an electrical load.

### TECHNICAL FIELD

The present disclosure relates generally to an internal combustion engine exhaust thermoelectric generator and methods of making and using the same.

### BACKGROUND

A thermoelectric (TE) module is a semiconductor-based electronic component that may be used for electric power generation. In other applications, a TE module may be applied as a heat pump or Peltier cooler. When a temperature differential is applied across a TE module, DC electric power is generated. As such, a TE module may be used to convert thermal energy to electrical energy.

Internal combustion engines convert the chemical energy of fuel into usable energy by combustion of the fuel. Typically, only a portion of the energy released in combustion of the fuel is converted by the internal combustion engine into desirable work. In some internal combustion engines, about 40 percent of the energy of combustion is lost through the exhaust gases—mainly in the form of waste heat.

### SUMMARY

An internal combustion engine exhaust thermoelectric generator includes a stainless steel exhaust gas heat exchanger having an interior portion defined by a stainless steel wall and having an exterior surface of the stainless steel wall distal to the interior portion. The exhaust gas heat exchanger receives a pressurized exhaust gas stream from the internal combustion engine and extracts thermal energy from the exhaust gas stream. At least one copper heat sink is in thermal contact with the exhaust gas heat exchanger to conduct thermal energy from the exhaust gas heat exchanger. A thermoelectric module having a hot side is disposed on a surface of the at least one copper heat sink. The thermoelectric module has a cold side distal to the hot side. The thermoelectric module converts thermal energy to electrical energy for consumption or storage by an electrical load. A liquid cooled heat exchanger is disposed on the cold side of the thermoelectric module to transfer thermal energy from the thermoelectric module to a liquid coolant passed through the liquid cooled heat exchanger.

### BRIEF DESCRIPTION OF THE DRAWINGS

Features and advantages of the present disclosure will become apparent by reference to the following detailed description and drawings, in which like reference numerals correspond to similar, though perhaps not identical, components. For the sake of brevity, reference numerals or features having a previously described function may or may not be described in connection with other drawings in which they appear.

FIG. 1 is a semi-schematic partially exploded perspective view of an example of a thermoelectric generator as disclosed herein;

FIG. 2 is a system interface diagram of an example of a thermoelectric generator as disclosed herein;

FIG. 3 is a semi-schematic cross-sectional view of the example depicted in FIG. 1;

FIG. 4 is a semi-schematic cross-sectional view of an example of a thermoelectric generator having a coaxial heat sink and heat exchangers as disclosed herein; and

FIG. 5 is a semi-schematic cross-sectional view of another example of a thermoelectric generator having a coaxial heat sink and heat exchangers as disclosed herein.

### DETAILED DESCRIPTION

Automotive exhaust thermoelectric generator (TEG) assemblies convert thermal energy from internal combustion engine exhaust to usable electrical energy. TEGs generally have a hot side, a cold side, and a thermoelectric module between the hot and the cold side. A TEG installed in, for example, an automotive exhaust system, may be subject to a thermal and chemical environment that accelerates corrosion and chemical deterioration of parts of the TEG exposed to exhaust gases. Exhaust TEGs use heat exchangers to extract thermal energy from an exhaust gas stream. If a TEG heat exchanger is made from a material that has high thermal conductivity, the TEG will be able to extract energy at a higher rate and be more efficient in converting the energy to electricity. Copper is a material with excellent thermal conductivity; however copper corrodes rapidly in the presence of hot exhaust gases. In order to improve corrosion resistance, a copper TEG hot side heat exchanger has been plated with nickel. In the exhaust TEG disclosed herein, the hot side heat exchanger may also be known as an exhaust gas heat exchanger. Nickel provides corrosion resistance, however nickel is relatively expensive, and it must be plated at a relatively high thickness to resist scratches during assembly and use. Other metals could be used for plating, however, the cost may be even higher than plating with nickel.

The internal combustion engine exhaust TEG disclosed herein includes a composite heat exchanger with durable and corrosion resistant stainless steel components that contact the exhaust gases. The composite heat exchanger also includes at least one copper heat sink to quickly and evenly draw heat from the stainless steel to the thermoelectric modules. The heat exchanger may include stainless steel mounting flanges that exhibit strength, durability, and galvanic compatibility with stainless steel exhaust pipes. The hot side heat exchanger may further include stainless steel fins to improve heat transfer capability of the exhaust gas heat exchanger. The fins may include louvers for further improvements in heat transfer capability of the heat exchanger.

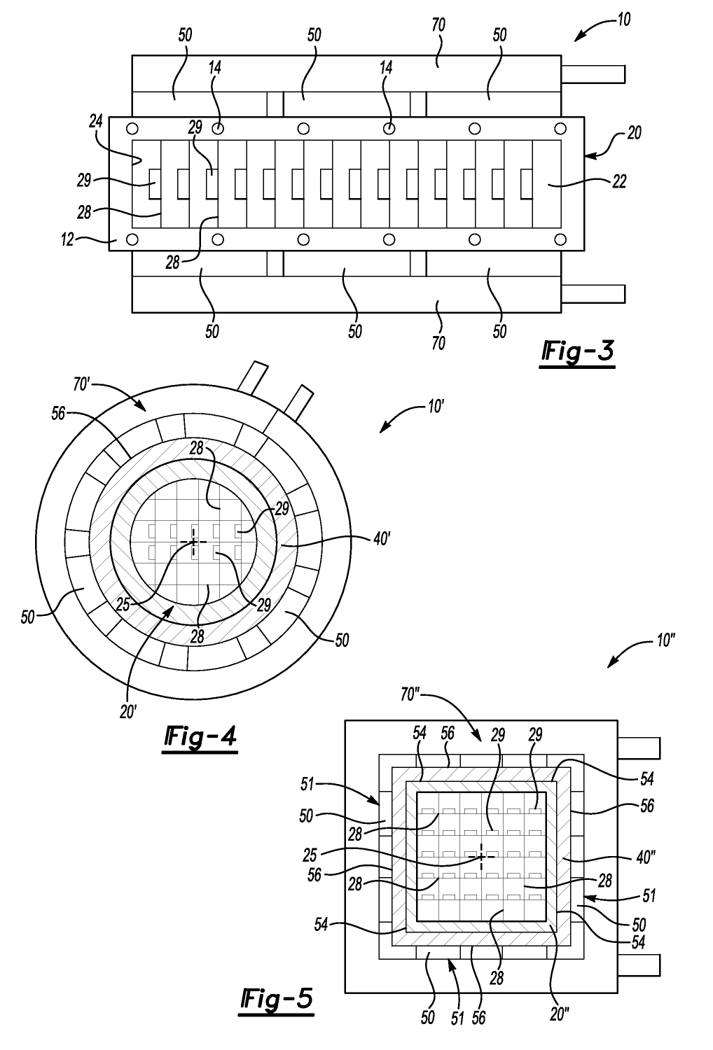

Referring now to FIGS. 1, 2, and 3 together, an internal combustion engine 30 exhaust TEG 10 includes a stainless steel exhaust gas heat exchanger 20. The exhaust gas heat exchanger 20 has an interior portion 22 defined by a stainless steel wall 24. The exhaust gas heat exchanger 20 also has an exterior surface 26 of the stainless steel wall 24 distal to the interior portion 22. The exhaust gas heat exchanger 20 receives a pressurized exhaust gas stream 32 from the internal combustion engine 30 and extracts thermal energy 34 from the exhaust gas stream 32.

Stainless steel as used herein means a steel alloy with a minimum of 11% chromium content by mass. Stainless steel may also be called corrosion-resistant steel (CRES). Many stainless steel alloys are acceptable as disclosed herein. Some examples of acceptable stainless steel alloys are: SAE 301, SAE 304, SAE 316L, SAE 321, and SAE 347.

The stainless steel exhaust gas heat exchanger 20 may include a stainless steel mounting flange 12 to sealingly connect to an exhaust pipe 36 of the internal combustion engine 30. The mounting flange 12 and the wall 24 may be formed from a single piece, by, for example, upsetting. In another example, the mounting flange 12 may be attached to the wall 24 by welding, brazing, or crimping. Examples of the heat exchanger mounting flange 12 may include threaded or unthreaded holes 14 for use with fasteners (not shown). It is to be understood that the exhaust gas stream 32 from the internal combustion engine 30 is at a higher pressure than the ambient atmosphere when the engine 30 is running and the pressurized exhaust gas stream 32 is contained in an exhaust system. For example, the pressurized exhaust gas stream 32 may have a gage pressure from about 5 kPa to about 80 kPa measured at the mounting flange 12. As such, the mounting flange 12 mates with the exhaust system to form a seal that substantially prevents the pressurized exhaust gases from leaking into the atmosphere at the flange 12.

Adapters and gaskets may be used to improve sealing and complement shapes and flow areas of the mating components. For example, a funnel shaped adapter as depicted in FIG. 1 may be installed between the mounting flange 12 and the exhaust pipe 36. It is to be understood that an example of a TEG 10 as disclosed herein may be configured without the mounting flange 12, and sealingly mated with the exhaust system using exhaust system joining techniques, including crimp connections, u-bolts, clamps, face seals, nipples, chemical sealers and bonding agents, welding and combinations thereof.

Examples of the engine exhaust TEG 10 disclosed herein may have stainless steel fins 28 included in the stainless steel exhaust gas heat exchanger 20. The stainless steel fins 28 are in contact with the wall 24 of the exhaust gas heat exchanger 20 to increase the rate of heat transfer from the exhaust gas stream 32. The rate of heat transfer from the exhaust gas stream 32 may be further increased by louvers 29 disposed on the stainless steel fins 28.

At least one copper heat sink 40 is in thermal contact with the exhaust gas heat exchanger 20 to conduct thermal energy 34 from the exhaust gas heat exchanger 20. It is to be understood that copper means pure copper, as well as alloys thereof with at least 90% copper calculated by mass.

As used herein, “in thermal contact with” means making surface-to-surface contact between bodies such that conductive heat transfer may occur. It is to be understood that a material such as “thermal paste,” a brazing material, or a welding material may be disposed between two bodies “in thermal contact.” It is not necessary for two bodies in thermal contact to be affixed to each other as long as they are in contact and conductive heat transfer can occur between the two bodies through the contacting surfaces.

It is to be further understood that the at least one copper heat sink 40 may be brazed to the exhaust gas heat exchanger 20. For example, the at least one copper heat sink 40 may be brazed to the exhaust gas heat exchanger 20 in a brazing oven or brazing furnace. In an example of the TEG disclosed herein, the at least one copper heat sink 40 may be attached to the exhaust gas heat exchanger 20 by fasteners such as bolts and rivets (not shown). The at least one copper heat sink 40 may be attached to the exhaust gas heat exchanger 20 by crimping, clamping, or by arranging in a tightly fitting enclosure (not shown).

The TEG 10 further includes at least one thermoelectric module 50 having a hot side 52 disposed on a surface 54 of the at least one copper heat sink 40. The at least one thermoelectric module 50 also has a cold side 56 distal to the hot side 52. The at least one thermoelectric module 50 converts thermal energy 34 to electrical energy 58 for consumption or storage by an electrical load 60. Non-limiting examples of the thermoelectric module 50 are the HZ-20 Thermoelectric Module available from Hi-Z Technology, Inc., 7606 Miramar Road, San Diego Calif. 92126-4210; and the TG12-6 thermoelectric module available from Marlow Industries, Inc., 10451 Vista Park Rd, Dallas, Tex. 75238. Non-limitative examples of electrical loads 60 are charging batteries, entertainment systems, lighting, electric motors, solenoids, climate control systems, instruments, navigation systems and communication systems.

As depicted in FIG. 1, the at least one thermoelectric module 50 may be an array 51 of thermoelectric modules 50. The thermoelectric modules 50 in an array 51 may be electrically connected to other modules 50 in the array 51 in series, parallel, or in a combination thereof. The array 51 may have more than one section disposed on portions of the surface 54 of the at least one copper heat sink 40, as shown in FIGS. 1 and 5.

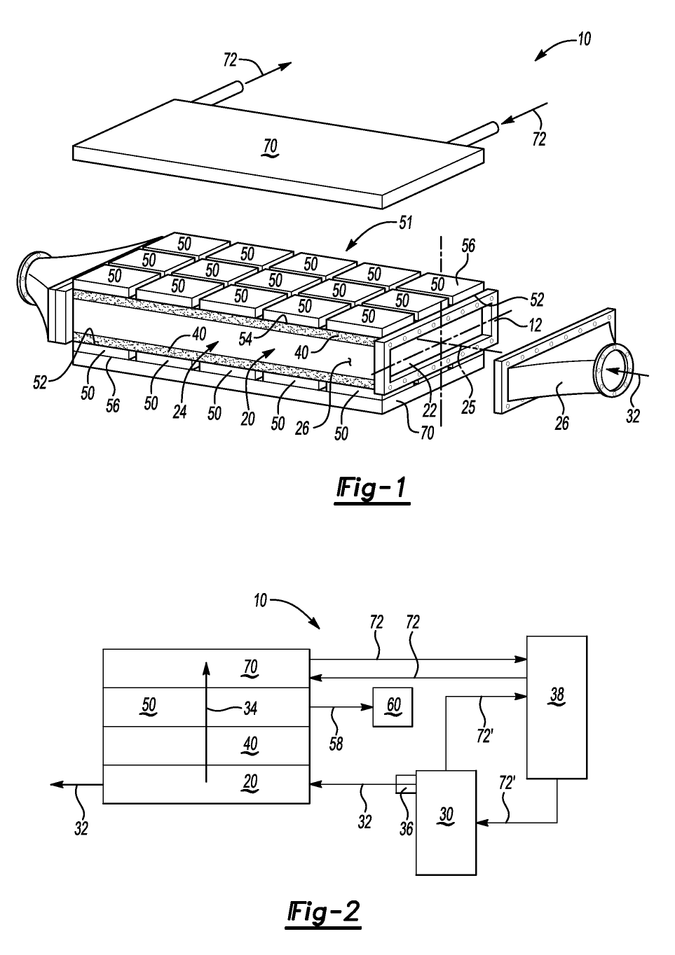

At least one liquid cooled heat exchanger 70 is disposed on the cold side 56 of the at least one thermoelectric module 50 to transfer thermal energy 34 from the at least one thermoelectric module 50 to a liquid coolant 72 passed through the at least one liquid cooled heat exchanger 70. Examples of the liquid coolant 72 include mixtures of water and coolant concentrate (antifreeze, an example of which is ethylene glycol) referred to in SAE J814 Engine Coolants, incorporated by reference herein. It is to be understood that the liquid coolant 72 disclosed herein is not limited to water/antifreeze mixtures. For example, liquids including natural and synthetic motor oils, hydraulic fluids and silicone may be used as the liquid coolant 72. As depicted in FIG. 2, the liquid coolant 72 may flow through an engine radiator 38 to cool the liquid coolant 72 and thereby cool the liquid cooled heat exchanger 70. The engine radiator 38 may be a liquid to air heat exchanger, including a typical automotive radiator. The engine radiator 38 may have engine coolant 72′ flowing therethrough. It is to be understood that heat exchanged from the liquid 72 through the engine radiator 38 may be transferred directly through tubes and fins of the radiator (not shown), or there may be an intermediate heat exchanger, for example an end-tank cooler (not shown).

Examples of the engine exhaust TEG 10 disclosed herein include other arrangements of the heat exchangers 20, 70, heat sink 40 and thermoelectric modules 50. For example, as depicted in FIG. 1, the at least one copper heat sink 40 may be two copper heat sinks 40 disposed on opposite sides of the exhaust gas heat exchanger 20 with the exhaust gas heat exchanger 20 interposed between the two copper heat sinks 40. In the example, the at least one liquid cooled heat exchanger 70 may be two liquid cooled heat exchangers 70 disposed on opposite sides of the engine exhaust TEG 10. As used herein, the term “opposite sides of the exhaust gas heat exchanger” means on opposed facing sides of the TEG 10 wherein a central axis 25 of exhaust flow is directly between the opposed facing sides. By way of further explanation using the orientation depicted in FIG. 1, left and right are not “opposite sides of the exhaust gas heat exchanger” as used herein because the central axis 25 of exhaust flow runs from right to left, therefore it cannot be between the two sides.

Still referring to FIGS. 1, 2 and 3, a method of converting thermal energy 34 to electrical energy 58 is disclosed herein. The method includes receiving a pressurized exhaust gas stream 32 from an internal combustion engine 30 in a stainless steel exhaust gas heat exchanger 20 having an interior portion 22 defined by a stainless steel wall 24 and having an exterior surface 26 of the stainless steel wall 24 distal to the interior portion 22. The method further includes extracting the thermal energy 34 at a rate of transfer from the exhaust gas stream 32 through the stainless steel wall 24 to at least one copper heat sink 40 in thermal contact with the exhaust gas heat exchanger 20. The at least one copper heat sink 40 may be brazed to the exhaust gas heat exchanger 20. In an example the method may include furnace brazing the at least one copper heat sink 40 to the exhaust gas heat exchanger 20.

Still further, the method includes conducting thermal energy 34 from the exhaust gas heat exchanger 20 to at least one thermoelectric module 50 having a hot side 52 disposed on a surface 54 of the at least one copper heat sink 40 and a cold side 56 distal to the hot side 52.

Yet further, the method includes converting at least a portion of the thermal energy 34 to electrical energy 58 within the thermoelectric module 50 for consumption or storage by an electrical load 60. As defined herein, converting thermal energy 34 to electrical energy 58 “within” the thermoelectric module is accomplished through application of the Peltier-Seebeck effect. It is to be further understood that the meaning of converting energy “within” the thermoelectric module 50 as used herein does not include exhaust-driven turbine generators.

The method also includes transferring a residual portion of the thermal energy 34 from the at least one thermoelectric module 50 to a liquid coolant 72 passed through at least one liquid cooled heat exchanger 70 disposed on the cold side 56 of the at least one thermoelectric module 50.

The method may include disposing stainless steel fins 28 in the interior portion 22 of the stainless steel exhaust gas heat exchanger 20. Louvers 29 may be disposed on the stainless steel fins 28.

It is to be understood that the at least one thermoelectric module 50 of the method disclosed herein may be an array 51 of thermoelectric modules 50. The array 51 of thermoelectric modules 50 may be electrically connected in series, parallel, or in a combination thereof.

A further example of the method as disclosed herein includes disposing two copper heat sinks 40 on opposite sides of the exhaust gas heat exchanger 20 with the exhaust gas heat exchanger 20 interposed between the two copper heat sinks 40. In this example, two liquid cooled heat exchangers 70 are disposed on opposite sides of the engine exhaust TEG 10.

Referring now to FIG. 4, the engine exhaust TEG 10′ may have the at least one copper heat sink 40′ coaxially surrounding the exhaust gas heat exchanger 20′. As depicted in FIG. 4, the at least one copper heat sink 40′ is substantially annular in a cross section taken normal to the central axis 25 of exhaust flow. In the example, the at least one liquid cooled heat exchanger 70′ coaxially surrounds the at least one copper heat sink 40′. Similarly to the at least one copper heat sink 40′, the at least one liquid cooled heat exchanger 70′ (as depicted in FIG. 4) is substantially annular in a cross section taken normal to the central axis 25 of exhaust flow.

The method of converting thermal energy 34 to electrical energy 58 is also disclosed wherein the at least one copper heat sink 40 coaxially surrounds the exhaust gas heat exchanger 20 and the at least one liquid cooled heat exchanger 70 coaxially surrounds the at least one copper heat sink 40.

It is to be understood that at least one copper heat sink 40′ may be brazed to the exhaust gas heat exchanger 20′. For example, the at least one copper heat sink 40′ may be brazed to the exhaust gas heat exchanger 20′ in a brazing oven or brazing furnace. Further, the at least one copper heat sink 40′ may be joined to the exhaust gas heat exchanger 20′ using welding techniques including pressure welding, roll-welding and explosive welding. It is to be further understood that the joining of the copper heat sink 40′ to the exhaust gas heat exchanger 20′ need not be performed on an otherwise finished heat exchanger; the copper and stainless steel may be joined at any stage during fabrication of the engine exhaust TEG 10′. The at least one copper heat sink 40′ may be attached to the exhaust gas heat exchanger 20′ by fasteners such as bolts and rivets (not shown). The at least one copper heat sink 40′ may be attached to the exhaust gas heat exchanger 20′ by crimping, clamping, or by arranging in a tightly fitting enclosure (not shown).

Referring now to FIG. 5, the engine exhaust TEG 10″ (similarly to the TEG 10′ shown in FIG. 4) may have the at least one copper heat sink 40″ coaxially surrounding the exhaust gas heat exchanger 20″. However, as depicted in FIG. 5, the at least one copper heat sink 40″ is substantially rectangular in a cross section taken normal to the central axis 25 of exhaust flow. In the example, the at least one liquid cooled heat exchanger 70″ coaxially surrounds the at least one copper heat sink 40″. As depicted in FIG. 5, the at least one liquid cooled heat exchanger 70″ is substantially rectangular in a cross section taken normal to the central axis 25 of exhaust flow.

It is to be further understood that at least one copper heat sink 40″ may be brazed to the exhaust gas heat exchanger 20″. For example, the at least one copper heat sink 40″ may be brazed to the exhaust gas heat exchanger 20″ in a brazing oven or brazing furnace. The at least one copper heat sink 40″ may be attached to the exhaust gas heat exchanger 20″ by fasteners such as bolts and rivets (not shown). The at least one copper heat sink 40″ may be attached to the exhaust gas heat exchanger 20″ by crimping, clamping, or by arranging in a tightly fitting enclosure (not shown).

Coaxial heat sinks in the disclosed TEG and method may have annular or rectangular cross sections as shown in the FIGS. 4 and 5 respectively, however, the cross sections may have any number of sides. For example, the heat sinks may have triangular, pentagonal, hexagonal or in general have an n-gon shaped cross section, where n is any natural number. It is to be understood that natural numbers, as used herein, are all positive integers and do not include zero.

It is to be understood that the ranges provided herein include the stated range and any value or sub-range within the stated range. For example, a range from about 5 kPa to about 80 kPa should be interpreted to include not only the explicitly recited limits of about 5 kPa to about 80 kPa, but also to include individual values, such as 15 kPa, 20 kPa, 31 kPa, 48 kPa, etc., and sub-ranges, such as from about 5 kPa to about 22 kPa, from about 26 kPa to about 48 kPa, etc. Furthermore, when “about” is utilized to describe a value, this is meant to encompass minor variations (up to +/−10%) from the stated value.

Further, it is to be understood that the terms connect/connected/connection”, “contact/contacting”, and/or the like are broadly defined herein to encompass a variety of divergent connected/contacting arrangements and assembly techniques. These arrangements and techniques include, but are not limited to (1) the direct communication between one component and another component with no intervening components therebetween; and (2) the communication of one component and another component with one or more components therebetween, provided that the one component being “connected to”/“in contact with” the other component is somehow in operative communication with the other component (notwithstanding the presence of one or more additional components therebetween).

While several examples have been described in detail, it will be apparent to those skilled in the art that the disclosed examples may be modified. Therefore, the foregoing description is to be considered non-limiting.

1. An internal combustion engine exhaust thermoelectric generator, comprising:
a stainless steel exhaust gas heat exchanger having an interior portion defined by a stainless steel wall and an exterior surface of the stainless steel wall distal to the interior portion, the exhaust gas heat exchanger to receive a pressurized exhaust gas stream from the internal combustion engine and to extract thermal energy from the exhaust gas stream;
at least one copper heat sink in thermal contact with the exhaust gas heat exchanger to conduct thermal energy from the exhaust gas heat exchanger;
at least one thermoelectric module having a hot side disposed on a surface of the at least one copper heat sink and a cold side distal to the hot side, wherein the at least one thermoelectric module converts thermal energy to electrical energy for consumption or storage by an electrical load; and
at least one liquid cooled heat exchanger disposed on the cold side of the at least one thermoelectric module to transfer thermal energy from the at least one thermoelectric module to a liquid coolant passed through the at least one liquid cooled heat exchanger.

2. The engine exhaust thermoelectric generator as defined in claim 1 wherein the stainless steel exhaust gas heat exchanger includes a stainless steel mounting flange to sealingly connect to an exhaust pipe of the internal combustion engine.

3. The engine exhaust thermoelectric generator as defined in claim 1 wherein the stainless steel exhaust gas heat exchanger includes stainless steel fins.

4. The engine exhaust thermoelectric generator as defined in claim 3 wherein the stainless steel fins include louvers disposed on the stainless steel fins.

5. The engine exhaust thermoelectric generator as defined in claim 1 wherein the at least one thermoelectric module is an array of thermoelectric modules.

6. The engine exhaust thermoelectric generator as defined in claim 5 wherein the array of thermoelectric modules is electrically connected in series, parallel, or in a combination thereof.

7. The engine exhaust thermoelectric generator as defined in claim 1 wherein the at least one copper heat sink comprises two copper heat sinks disposed on opposite sides of the exhaust gas heat exchanger with the exhaust gas heat exchanger interposed therebetween, and wherein the at least one liquid cooled heat exchanger is two liquid cooled heat exchangers disposed on opposite sides of the engine exhaust thermoelectric generator.

8. The engine exhaust thermoelectric generator as defined in claim 1 wherein the at least one copper heat sink coaxially surrounds the exhaust gas heat exchanger, and the at least one liquid cooled heat exchanger coaxially surrounds the at least one copper heat sink.

9. The engine exhaust thermoelectric generator as defined in claim 1 wherein the at least one copper heat sink is brazed to the exhaust gas heat exchanger.

10. A method of making the engine exhaust thermoelectric generator as defined in claim 1 wherein the at least one copper heat sink is furnace brazed to the exhaust gas heat exchanger.

11. A method of converting thermal energy to electrical energy, comprising:
receiving a pressurized exhaust gas stream from the internal combustion engine in a stainless steel exhaust gas heat exchanger having an interior portion defined by a stainless steel wall and having an exterior surface of the stainless steel wall distal to the interior portion;
extracting thermal energy at a rate of transfer from the exhaust gas stream through the stainless steel wall to at least one copper heat sink in thermal contact with the exhaust gas heat exchanger;
conducting thermal energy from the exhaust gas heat exchanger to at least one thermoelectric module having a hot side disposed on a surface of the copper heat sink and a cold side distal to the hot side;
converting at least a portion of the thermal energy to electrical energy within the thermoelectric module for consumption or storage by an electrical load; and
transferring a residual portion of the thermal energy from the at least one thermoelectric module to a liquid coolant passed through at least one liquid cooled heat exchanger disposed on the cold side of the at least one thermoelectric module.

12. The method as defined in claim 11, further comprising sealingly connecting a stainless steel mounting flange of the stainless steel exhaust gas heat exchanger to an exhaust pipe of the internal combustion engine.

13. The method as defined in claim 11, further comprising disposing stainless steel fins in the interior portion of the stainless steel exhaust gas heat exchanger.

14. The method as defined in claim 13, further comprising disposing louvers on the stainless steel fins.

15. The method as defined in claim 11 wherein the at least one thermoelectric module is an array of thermoelectric modules.

16. The method as defined in claim 15, further comprising electrically connecting the array of thermoelectric modules in series, in parallel, or in a combination thereof.

17. The method as defined in claim 11 wherein the at least one copper heat sink is two copper heat sinks disposed on opposite sides of the exhaust gas heat exchanger with the exhaust gas heat exchanger interposed therebetween, and wherein the at least one liquid cooled heat exchanger is two liquid cooled heat exchangers disposed on opposite sides of the engine exhaust thermoelectric generator.

18. The method as defined in claim 11 wherein the at least one copper heat sink coaxially surrounds the exhaust gas heat exchanger, and the at least one liquid cooled heat exchanger coaxially surrounds the at least one copper heat sink.

19. The method as defined in claim 11 wherein the at least one copper heat sink is brazed to the exhaust gas heat exchanger.

20. The method as defined in claim 11, further comprising furnace brazing the at least one copper heat sink to the exhaust gas heat exchanger.
